(19) United States
(12) Patent Application Publication
(10) Pub. No.: US 2015/0311425 A1
(43) Pub. Date: Oct. 29, 2015

(54) METHOD FOR MANUFACTURING PIEZOELECTRIC CERAMIC, PIEZOELECTRIC CERAMIC, AND PIEZOELECTRIC ELEMENT

(71) Applicants: TOYAMA PREFECTURE, Toyama-shi, Toyama (JP); HITACHI METALS, LTD., Minato-ku, Tokyo (JP)

(72) Inventors: Shuji YAMANAKA, Mishima-gun (JP); Genei NAKAJIMA, Mishima-gun (JP); Tomotsugu KATO, Mishima-gun (JP); Kenya TANAKA, Mishima-gun (JP); Tomoaki KARAKI, Imizu-shi (JP)

(21) Appl. No.: 14/647,146

(22) PCT Filed: Nov. 27, 2013
(86) PCT No.: PCT/JP2013/081929

§ 371 Date: May 26, 2015

(30) Foreign Application Priority Data
Nov. 27, 2012 (JP) 2012-258677

(51) Int. Cl. H01L 41/187; H01L 41/43

(52) U.S. Cl. CPC H01L 41/1871; H01L 41/43

(57) ABSTRACT

A method for manufacturing piezoelectric ceramic including the steps of: preparing a raw material so as to contain A, B, Ba and Zr as major constituents in a composition ratio represented by the following formula: (1-s)ABO₃-sBaZrO₃ (where A is at least one element selected from alkali metals, B is at least one of transition metal elements and includes Nb, 0.06<s≦0.15); molding the raw material to obtain a molded body; sintering the molded body in a reducing atmosphere; and subjecting a sintered body obtained at the sintering step to a heat treatment in an oxidative atmosphere.

### TECHNICAL FIELD

The present invention relates to a method for manufacturing lead-free piezoelectric ceramic, a piezoelectric ceramic, and a piezoelectric element.

### BACKGROUND ART

Conventionally, various materials including ceramics, monocrystals, thick films, thin films, etc., have been developed as the piezoelectric material for use in piezoelectric devices. Among others, a piezoelectric ceramic which is made of PbZrO₃—PbTiO₃ (PZT) that is a lead-containing perovskite ferroelectric exhibits excellent piezoelectric characteristics. Therefore, PZT ceramics have been widely used in the fields of electronics, mechatronics, automobiles, etc.

However, in recent years, due to increasing awareness of environmental protection, the trend of avoiding use of metals such as Pb, Hg, Cd, and Cr⁶⁺ in electronic and electric devices has been growing. In and around Europe, the directive on the restriction of the use (RoHS directive) took effect and was enforced.

Considering use of conventional lead-containing piezoelectric ceramics in a wide area, research on environment-friendly, lead-free piezoelectric materials is important and exigent. Therefore, lead-free piezoelectric ceramics which can exhibit performance comparable to conventional PZT piezoelectric ceramics have been occupying the interest of researchers.

Perovskite compounds are generally expressed in the form of “ABO₃”. Among these compounds, ceramics in which an alkali metal is used at the A site of the perovskite compound and Nb, Ta, Sb, or the like, is used at the B site have been researched in recent years as lead-free composition ceramics that have relatively high piezoelectric characteristics.

For example, Patent Document 1 discloses an alkali metal-containing niobium oxide-based piezoelectric ceramic whose composition is, specifically, Liₓ(K_{1-y}Na_{y})₁₋ₓ(Nb_{1-z}Ta_{z})O₃ (where x=0.001 to 0.2, y=0 to 0.8, z=0 to 0.4).

Patent Document 2 discloses a piezoelectric solid solution composition whose major constituent is a composition expressed by formula {Mₓ(Na_{y}Li_{z}K_{1-y-z})₁₋ₓ}₁₋ₘ{(Ti₁₋ᵤ₋ᵥZrᵤHfᵥ)ₓ(Nb_{1-w}Ta_{w})₁₋ₓ}O₃ (M is a combination of at least one selected from the group consisting of (Bi_{0.5}K_{0.5}), (Bi_{0.5}Na_{0.5}) and (Bi_{0.5}Li_{0.5}) and at least one selected from the group consisting of Ba, Sr, Ca and Mg; and the ranges of x, y, z, u, v, w and m are 0.06<x≦0.3, 0≦y≦1, 0≦z≦0.3, 0≦y+z≦1, 0<u≦1, 0≦v≦0.75, 0≦w≦0.2, 0<u+v≦1 and −0.06≦m≦0.06).

In manufacture of lead-containing and lead-free piezoelectric ceramics, the piezoelectric ceramics are made of the above-described perovskite compound. Therefore, commonly, a sintering step in an oxidative atmosphere is employed in order to avoid decomposition of the compound. And, Ag electrodes are formed on the piezoelectric ceramics in order to avoid degeneration by oxidation in the sintering step. Along with the trend of resource saving in recent years, using a base metal as the electrodes instead of expensive Ag electrodes has been attempted.

For example, Patent Document 3 discloses a method for manufacturing piezoelectric ceramic including the sintering step of sintering a multilayer structure consisting of a piezoelectric ceramic layer precursor which contains ceramic composition powder of a predetermined composition and an internal electrode precursor which contains a base metal as the electrically-conductive material in the first reducing atmosphere (oxygen partial pressure: 10⁻⁶ to 10⁻⁹ atm), and the heat treatment step of heating the sintered multilayer structure in the second reducing atmosphere (oxygen partial pressure: 10⁻² to 10⁻⁶ atm) of which the oxygen partial pressure is higher than that of the first reducing atmosphere.

### CITATION LIST

### Patent Literature

Patent Document 1: Japanese Laid-Open Patent Publication No. 2000-313664

Patent Document 2: WO 2008/143160

Patent Document 3: Japanese Laid-Open Patent Publication No. 2006-100598

### SUMMARY OF INVENTION

### Technical Problem

These lead-free piezoelectric ceramics are required to have a practical piezoelectric constant d33.

In view of such a problem, the present invention provides a lead-free piezoelectric ceramic which is excellent in the piezoelectric constant d33 as compared with conventional lead-free piezoelectric ceramics, a piezoelectric element, and a method for manufacturing piezoelectric ceramic.

### Solution to Problem

A method for manufacturing piezoelectric ceramic of the present invention includes the steps of: preparing a raw material so as to contain A, B, Ba and Zr as major constituents in a composition ratio represented by the following formula: (1-s)ABO₃-sBaZrO₃ (where A is at least one element selected from alkali metals, B is at least one of transition metal elements and includes Nb, 0.06<s≦0.15); molding the raw material to obtain a molded body; sintering the molded body in a reducing atmosphere; and subjecting a sintered body obtained at the sintering step to a heat treatment in an oxidative atmosphere.

Another method for manufacturing piezoelectric ceramic of the present invention includes the steps of: preparing a raw material so as to contain A, B, Ba, Zr, R, M and Ti as major constituents in a composition ratio represented by the following formula: (1-s-t)ABO₃-sBaZrO₃-t(R.M)TiO₃ (where A is at least one element selected from alkali metals, B is at least one of transition metal elements and includes Nb, R is at least one of rare earth elements (including Y), M is at least one element selected from alkali metals, 0.05<s≦0.15, 0<t≦0.03, s+t>0.06); molding the raw material to obtain a molded body; sintering the molded body in a reducing atmosphere; and subjecting a sintered body obtained at the sintering step to a heat treatment in an oxidative atmosphere.

The A may include at least Li, K and Na.

The M may include at least Na.

In the sintering step, an oxygen partial pressure of the reducing atmosphere may be not more than 10⁻⁴ kPa.

In the sintering step, the oxygen partial pressure of the reducing atmosphere may be not less than 10⁻¹² kPa and not more than 10⁻⁴ kPa.

In the sintering step, the reducing atmosphere may contain hydrogen in a range of not less than 0.01% and not more than 5%.

In the sintering step, a sintering temperature may be not less than 1100° C. and not more than 1300° C.

In the sintering step, a sintering duration may be not less than 0.1 hour and not more than 30 hours.

In the heat treatment step, an oxygen partial pressure of the oxidative atmosphere may exceed 10⁻⁴ kPa.

In the heat treatment step, a heat treatment temperature may be not less than 500° C. and not more than 1200° C.

A piezoelectric ceramic of the present invention is manufactured by any of the above-described methods.

The s may be in a range of 0.065≦s≦0.10, and a piezoelectric constant d33 of the piezoelectric ceramic may be not less than 250 pC/N.

The s may be in a range of 0.065≦s≦0.10, the t may be in a range of 0.005<t≦0.015, and a piezoelectric constant d33 of the piezoelectric ceramic may be not less than 270 pC/N.

A piezoelectric element of the present invention includes: the piezoelectric ceramic as set forth in any of the above paragraphs; and a plurality of electrodes which are in contact with the piezoelectric ceramic.

The plurality of electrodes may contain a base metal.

### Advantageous Effects of Invention

The present invention enables to provide a method of manufacturing a lead-free piezoelectric ceramic in which the piezoelectric constant d33 after polarization can be improved as compared with the conventional ones. Not only the piezoelectric constant d33 but also the Curie temperature can be improved in a balanced fashion. Thus, a lead-free piezoelectric ceramic and piezoelectric element which exhibit excellent piezoelectric characteristics can be provided.

### BRIEF DESCRIPTION OF DRAWINGS

FIG. 1 is a flowchart illustrating an embodiment of a method for manufacturing piezoelectric ceramic of the present invention.

FIG. 2 is a graph showing the temperature pattern of heating (sintering step, heat treatment step) of Example 1.

FIG. 3 is a diagram showing the composition of piezoelectric ceramics of Examples and Comparative Examples.

FIG. 4 is a cross-sectional SEM photograph showing a piezoelectric ceramic of Example 1.

FIG. 5 is a graph showing the relationship between s of Formula (2) and the piezoelectric constant d33.

FIG. 6 is a graph showing the relationship between s of Formula (2) and the electromechanical coupling factor Kp.

FIG. 7 is a graph showing the relationship between s of Formula (1) and the piezoelectric constant d33 for respective hydrogen concentrations during sintering.

FIG. 8 is a graph showing the relationship between s of Formula (2) and the piezoelectric constant d33 for respective hydrogen concentrations during sintering.

FIG. 9 is a graph showing the relationship between s of Formula (1) and the piezoelectric constant d33 for respective oxygen partial pressures during recovery heat treatment.

### DESCRIPTION OF EMBODIMENTS

The inventors of the present application carried out detailed research on the constituent materials and manufacturing method of lead-free piezoelectric ceramics. As a result, it was found that a piezoelectric ceramic which has a high piezoelectric constant d33, as compared with conventional methods where the sintering is carried out in the air, can be obtained by molding a ceramic raw material which has a specific composition ratio into a molded body and then subjecting the molded body to sintering in a reducing atmosphere (hereinafter, “reductive sintering”) and a heat treatment in an oxidative atmosphere (hereinafter, “recovery heat treatment”). Also, it was found that this piezoelectric ceramic has a high Curie temperature as compared with a case where the sintering is carried out in the air. The present inventors conceived the present invention based on such knowledge.

Hereinafter, embodiments of a method for manufacturing piezoelectric ceramic, a piezoelectric ceramic and a piezoelectric element according to the present invention will be described in detail. The following description is merely exemplary for enabling those skilled in the art to fully understand the embodiments of the present invention. The present invention is not limited to the embodiments that will be described below.

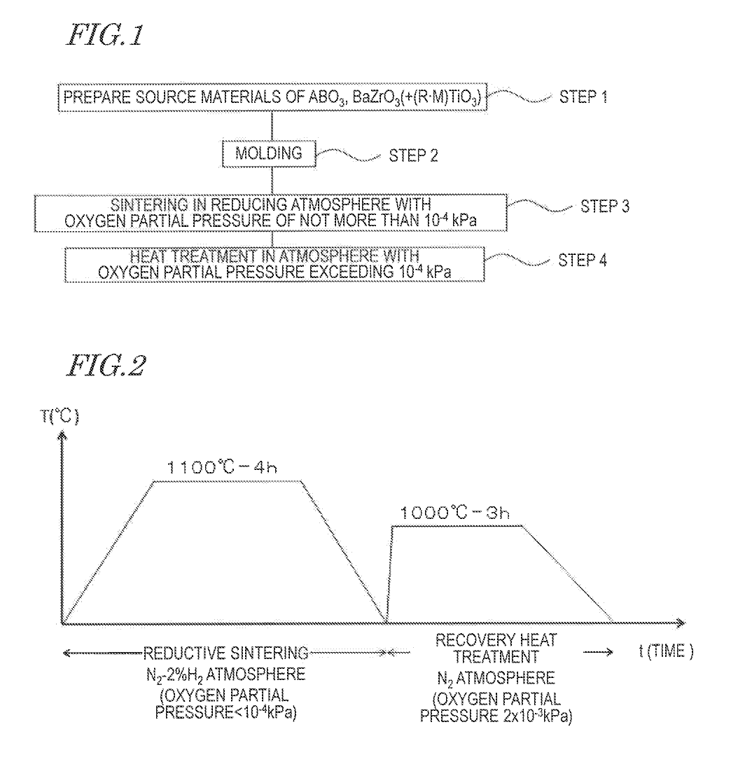

As shown in FIG. 1, a method for manufacturing piezoelectric ceramic of the present embodiment includes the step of preparing a raw material whose major constituents are A, B, Ba and Zr in a composition ratio represented by the following formula: (1-s)ABO₃-sBaZrO₃ (where A is at least one element selected from the alkali metals, B is at least one element selected from the transition metal elements and includes Nb, 0.06<s≦0.15) (Step 1), the step of molding the prepared raw material into a molded body (Step 2), the step of subjecting the molded body to reductive sintering in a reducing atmosphere (Step 3), and the step of subjecting the sintered body obtained by the sintering step to a recovery heat treatment in an oxidative atmosphere (Step 4).

The above-described formula may be represented by the following formula: (1-s−t)ABO₃-sBaZr₃-t(R.M)TiO₃ (where A is at least one element selected from the alkali metals, B is at least one element selected from the transition metal elements and includes Nb, R is at least one of the rare earth elements (including Y), M is at least one element selected from the alkali metals, 0.05<s≦0.15, 0<t≦0.03, s+t>0.06). Hereinafter, the steps are sequentially described.

(1) Step of Preparing Raw Material (Step 1)

A ceramic which is a major part of the piezoelectric ceramic of the present embodiment includes ceramic compositions represented by ABO₃ and BaZrO₃. The ceramic may further include a ceramic composition represented by (R.M)TiO₃.

[ABO₃]

In the present embodiment, the composition represented by ABO₃ is an alkali metal-containing niobium oxide. As described above, A is at least one element selected from the alkali metals, and B is at least one element selected from the transition metal elements and includes Nb. The alkali metal-containing niobium oxide of this composition is known as the composition of a piezoelectric ceramic having a tetragonal perovskite structure which is capable of achieving a higher piezoelectric constant than the conventional ones, and also exhibits a high piezoelectric constant in the present embodiment.

Specifically, in an alkali metal-containing niobium oxide-based composition represented by ABO₃, A is at least one selected from the alkali metals (Li, Na, K). Preferably, A includes Li, K and Na.

More specifically, it is preferably represented by the following formula: K_{1-x-y}NaₓLi_{y}(Nb_{1-z}Q_{z})O₃. Here, Q is at least one of the transition metal elements other than Nb, and x, y and z satisfy 0<x<1, 0<y<1 and 0≦z≦0.3, respectively.

When both K and Na are included as the alkali metals, high piezoelectric characteristics can be exhibited as compared with a case where K or Na is solely included. Li can provide the effect of increasing the Curie temperature and the effect of increasing the sinterability and hence improving the piezoelectric characteristics, and also exhibits the effect of improving the mechanical strength. Note that if the content y of Li exceeds 0.3, the piezoelectric characteristics of the composition are likely to decrease. Therefore, the content y of Li in the alkali metal is preferably 0<y≦0.3. The ranges of x, y and z are, more preferably, 0.3≦x≦0.7, 0.05≦y≦0.2 and 0≦z≦0.2.

[BaZrO₃]

When used, BaZrO₃ is mixed with the alkali metal-containing niobium oxide which is represented by ABO₃ and therefore can exhibit the effect of improving the piezoelectric constant d33 of a piezoelectric ceramic obtained by the manufacturing method of the present invention. If a piezoelectric ceramic is manufactured by the same method as the manufacturing method of the present invention using only the alkali metal-containing niobium oxide without addition of BaZrO₃, the piezoelectric constant d33 of a resultant piezoelectric ceramic would not improve as will be described later with comparative examples. Also, BaZrO₃ can provide the effect of increasing the dielectric constant.

[(R.M)TiO₃]

(R.M)TiO₃ is a ceramic composition which has a rhombohedral perovskite structure. The composition represented by (R.M)TiO₃ is mixed with the composition represented by ABO₃, whereby a piezoelectric ceramic which has a tetragonal-rhombohedral phase boundary is obtained. This piezoelectric ceramic exhibits more excellent piezoelectric characteristics.

In (R.M)TiO₃, R is at least one of the rare earth elements including Y. Specifically, R is preferably at least one selected from Y, La and Ce. M is at least one selected from the alkali metals. Specifically, M includes at least one selected from the group consisting of Li, Na and K. R is preferably La. M is preferably Na.

Conventionally, a ceramic which has a composition represented by (Bi.M)TiO₃ is used as the rhombohedral perovskite structure compound. However, in the ceramic of this composition, Bi readily volatilizes during the reductive sintering, so that it is difficult to obtain a piezoelectric ceramic which has a desired composition. The rare earth elements, such as La, Y and Ce, oxides of which have a low standard free energy of formation, play a role equivalent to Bi and are unlikely to volatilize. Therefore, inclusion of (R.M)TiO₃ facilitates adjustment of the composition of a piezoelectric ceramic which is to be manufactured.

[Composition Ratio]

When the piezoelectric ceramic includes ABO₃ and BaZrO₃ as the major constituents as described above, it is preferred that these compositions are included in the piezoelectric ceramic in a ratio represented by Formula (1) shown below.

(1-s)ABO₃-sBaZrO₃(0.06<s≦0.15) (1)

When the content of BaZrO₃ is in the range of 0.06<s≦0.15, a piezoelectric ceramic whose piezoelectric constant d33 and Curie temperature are both higher than those of one sintered in the air can be obtained. On the other hand, when s is not more than 0.06, it is difficult to obtain a piezoelectric ceramic whose piezoelectric constant d33 is higher than that of one sintered in the air. Further, the Curie temperature decreases so that the resultant ceramic cannot be applied to practical use. Further, when s exceeds 0.15, the resultant piezoelectric constant is excessively low so that it is difficult to obtain a practical piezoelectric ceramic. A more preferred range of s is 0.065≦s≦0.10.

When the piezoelectric ceramic includes ABO₃, BaZrO₃ and (R.M)TiO₃ as the major constituents, it is preferred that these compositions are included in the piezoelectric ceramic in a ratio represented by Formula (2) shown below.

(1-s−t)ABO₃-sBaZrO₃-t(R.M)TiO₃

(0.05<s≦0.15, 0<t≦0.03, s+t>0.06) (2)

Inclusion of (R.M)TiO₃ enables, as described above, to obtain a piezoelectric ceramic having a phase boundary which is attributed to the reductive sintering while suppressing volatilization of the raw material due to the sintering and suppressing the variation of the composition.

When s is not more than 0.05 in Formula (2) shown above, it is difficult to obtain a piezoelectric ceramic whose piezoelectric constant d33 is higher than that of one sintered in the air. Further, the Curie temperature decreases so that the resultant ceramic cannot be applied to practical use. Further, when s exceeds 0.15, the resultant piezoelectric constant is excessively low so that it is difficult to obtain a practical piezoelectric ceramic.

When t is 0 in Formula (2) shown above, the composition of a piezoelectric ceramic having a phase boundary is not achieved, and the effect of improving the piezoelectric characteristics is less likely to be achieved. When t exceeds 0.03, the used amount of expensive La or the like increases, and the raw material cost also increases. From these viewpoints, more preferred ranges of s and t are 0.065≦s≦0.11 and 0.005≦t≦0.025. Still more preferred ranges of s and t are 0.065≦s≦0.10 and 0.005≦t≦0.020.

Note that, when the sum of s and t is smaller than 0.06 in Formula (2), it is difficult to obtain a piezoelectric ceramic whose piezoelectric constant d33 is higher than that of one sintered in the air. Thus, s and t satisfy the relationship of s+t>0.06.

In the present invention, the major constituent refers to one that contains 80 mol % or more of Formulae (1) and (2) shown above.

In Formulae (1) and (2) shown above, (R.M) refers to (R_{0.5}M_{0.5}).

[Source Material]

In the step of preparing the raw material, the above-described compositions of ABO₃, BaZrO₃ and (R.M)TiO₃ can be weighed with the expectation that the ratio represented by Formula (1) or (2) shown above is achieved, and mixed together. Alternatively, the elements of A, B, Ba and Zr themselves, or oxides, carbonates or oxalates containing A, B, Ba and Zr, may be weighed and mixed together such that A, B, Ba and Zr are contained in a composition ratio represented by Formula (1). Likewise, the elements of A, B, Ba, Zr, R, M and Ti themselves, or oxides, carbonates or oxalates containing A, B, Ba, Zr, R, M and Ti, may be weighed and mixed together such that A, B, Ba, Zr, R, M and Ti are contained in a composition ratio represented by Formula (2). The raw material is thoroughly mixed and ground using a ball mill or the like according to a common procedure for manufacture of ceramics by sintering.

Plate crystal powder may be used as a starting material which contains any one or more elements of A, B, Ba, Zr, R, M and Ti in Formulae (1) and (2) shown above. For example, plate crystal powder having a composition of (K_{1-x-y}NaₓLi_{y})NbO₃, or the like, may be used as A, B in Formulae (1) and (2) shown above. In this case, mixing the plate crystal powder in the range of not more than 0.5 to 10 mol % with respect to the entire starting material of the piezoelectric ceramic is preferred. This leads to a higher orientation than a sintered body in which a material obtained by simply mixing raw materials without using plate crystal powder is used, and therefore, polarization readily occurs. As a result, a piezoelectric ceramic having a large piezoelectric constant d33 is obtained.

[Other Source Materials]

So long as a composition represented by Formula (1) or (2) shown above is included as a major constituent, the piezoelectric ceramic may include other additives. For example, the piezoelectric ceramic of the present embodiment may include a perovskite structure composition other than the composition represented by Formula (1) or (2) shown above in the range of not more than 20 mol % with respect to the entire piezoelectric ceramic.

(2) Presintering Step

In the above-described raw material preparing step, it is preferred that the prepared raw material is presintered before being molded. The presintering is preferably carried out in the air at a temperature of not less than 900° C. and not more than 1100° C. A more preferred range of the temperature is not less than 950° C. and not more than 1080° C. The retention time is preferably not less than 0.5 hour and not more than 30 hours. A more preferred range of the retention time is not less than 1 hour and not more than 10 hours.

(3) Molding Step (Step 2)

Next, the raw material is molded into the shape of a piezoelectric ceramic which is determined according to its use. In the molding, a molding method which is known in the field of piezoelectric ceramics may be used. For example, the raw material may be molded into the shape of a sheet, and the sheets of the raw material may be stacked up. A paste for the internal electrode may be applied over the surfaces of the sheets before the sheets are stacked up. Alternatively, the raw material may be molded into a desired bulk shape.

When the raw material of the plate crystal powder is used, it is preferred that the faces of the plates of the plate crystal powder are oriented in the same direction during the molding. In the sintering step, the other raw materials undergo grain growth along the crystallographic orientation of the oriented plate crystal powder, and therefore, a crystallographically-oriented sintered body can be obtained. Inside the crystallographically-oriented sintered body, the polarizable axes of the crystals are oriented in the same direction. In this sintered body, polarization readily occurs as compared with a sintered body of a material which is prepared by simply mixing raw materials without using plate crystal powder. As a result, a piezoelectric ceramic which has a large piezoelectric constant d33 is obtained.

(4) Reductive Sintering Step (Step 3)

The resultant molded body is sintered in a reducing atmosphere. Thus, in the case where the piezoelectric ceramic of the present embodiment is realized as a piezoelectric element, the internal electrode can be made of a base metal which is susceptible to oxidation, e.g., Cu, Ni, or an alloy thereof, and sintered concurrently.

The reducing atmosphere is preferably a reducing gas which contains hydrogen. For example, it may be a nitrogen gas which contains hydrogen in the range of not less than 0.01% and not more than 5%. If the hydrogen content is less than 0.01%, the reducing power is insufficient so that it is difficult to obtain a piezoelectric ceramic which has a large piezoelectric constant d33. If the hydrogen content exceeds 5%, the proportion of hydrogen that is combustible is large so that handling of the furnace is difficult. A more preferred range of the concentration of hydrogen is not less than 0.05% and not more than 3%. A still more preferred range is not less than 0.1% and not more than 2%. The pressure of the reducing atmosphere is preferably around the atmospheric pressure. The piezoelectric ceramic of the present embodiment can be manufactured in a common mass production furnace as compared with a case of a reduced-pressure atmosphere, and the manufacturing cost can be reduced because a reduced-pressure environment is not used. Further, it is not necessary to expend time to configure the reduced-pressure environment, and therefore, the time required for manufacture of the piezoelectric ceramic can be reduced.

In the reducing atmosphere, the oxygen partial pressure is preferably not more than 10⁻⁴ kPa. If the oxygen partial pressure exceeds 10⁻⁴ kPa, the effect of improving the piezoelectric constant d33 decreases even when the recovery heat treatment is carried out after that in the oxidative atmosphere. Although the reasons for this are not clear, it is probably because a composition which has a few oxygen defects is more likely to form a solid solution with ABO₃ than a composition in which the ratio of Ba, Zr and O is perfectly 1:1:3, and a sintered body which is capable of realizing a high piezoelectric constant d33 can be readily obtained. It is estimated that, by subjecting such a resultant sintered body to a recovery heat treatment, the oxygen defects of the sintered body are complemented with oxygen, whereby a piezoelectric ceramic of a high piezoelectric constant d33 which can tolerate a polarization treatment is obtained. It is also estimated that the high piezoelectric constant is achieved because the resultant structural phase boundary is a tetragonal-rhombohedral phase boundary, which is the same structural phase boundary as those of lead-containing piezoelectric elements.

If the oxygen partial pressure in the reducing atmosphere exceeds 10⁻⁴ kPa, the piezoelectric constant d33 decreases. In the case where a base metal-based electrode paste is employed for the internal electrode, the electrode paste oxidizes.

The oxygen partial pressure has no particular lower limit. However, if the oxygen partial pressure is less than 10⁻¹² kPa, the reducing power is excessively large so that the constituents such as Na and K are reduced and volatilized during the sintering, and there is a probability that the composition of the piezoelectric ceramic greatly varies. Thus, the oxygen partial pressure is preferably not less than 10⁻¹² kPa.

At the reductive sintering step and the recovery heat treatment step which will be described later, the oxygen partial pressure in the heat treatment atmosphere can be measured using a commercially-available oximeter which has a YSZ (yttria stabilized zirconia) sensor.

The sintering temperature is preferably not less than 1100° C. and not more than 1300° C. If the sintering temperature is less than 1100° C., the raw material is not sufficiently sintered so that conduction readily occurs while polarization is unlikely to occur, and as a result, appropriate characteristics cannot be obtained in some cases. If the sintering temperature exceeds 1300° C., part of the elements which are constituents of the piezoelectric ceramic precipitates, and there is a probability that a ceramic which has high piezoelectric characteristics cannot be obtained. More preferably, the sintering temperature is not less than 1150° C. and not more than 1280° C. The sintering duration is preferably not less than 0.5 hour and not more than 30 hours. If the sintering duration is shorter than 0.5 hour, the molded body is not completely sintered in some cases. If the sintering duration is longer than 30 hours, part of the elements which are constituents of the piezoelectric ceramic volatilize, and there is a probability that a ceramic which has high piezoelectric characteristics cannot be obtained. More preferably, the sintering duration is not less than 1 hour and not more than 10 hours.

(5) Recovery Heat Treatment Step (Step 4)

The sintered body obtained by the reductive sintering step is subjected to a heat treatment in a predetermined atmosphere. During the heat treatment, the oxygen partial pressure in the atmosphere preferably exceeds 10⁻⁴ kPa. This is likely to improve the piezoelectric constant d33 of the piezoelectric ceramic. Although the reasons for this are not clear, it is probably because, by performing the heat treatment in the atmosphere in which the oxygen partial pressure exceeds 10⁻⁴ kPa, the oxygen defects, such as BaZrO₃₋ₘ, are complemented with oxygen, so that a tetragonal-rhombohedral structural phase boundary clearly emerges. As a result, it is estimated that, the mole number of oxygen is optimized, and a piezoelectric ceramic of a perovskite structure is obtained in which the mole number of the A site:the mole number of the B site:the mole number of oxygen is closer to 1:1:3.

If the oxygen partial pressure is not more than 10⁻⁴ kPa, the resistance of the piezoelectric ceramic is low so that conduction readily occurs. Thus, it is difficult to obtain a ceramic which has piezoelectric characteristics.

In the case where the piezoelectric ceramic of the present embodiment is realized as a piezoelectric element, it is preferred that the oxygen partial pressure is more than 10⁻⁴ kPa and not more than 10⁻² kPa in order to suppress oxidation of the internal electrode included in the piezoelectric element. When a noble metal-based electrode such as an Ag—Pd alloy is used, performing the recovery heat treatment in the air enables to obtain a piezoelectric ceramic in which the piezoelectric constant d33 and the Curie point Tc are further improved.

For the same reasons as those mentioned in connection with the reductive sintering step, it is preferred that during the recovery heat treatment the pressure of the atmosphere is the atmospheric pressure. So long as the above-described oxygen partial pressure is achieved, the atmosphere during the recovery heat treatment may contain any other inert gas, such as nitrogen or argon.

The temperature of the recovery heat treatment is preferably not less than 500° C. and not more than 1200° C. If the temperature of the heat treatment is less than 500° C., oxygen defects are not sufficiently complemented with oxygen. Therefore, only a piezoelectric ceramic which cannot be polarized by a polarization treatment is obtained, and a high piezoelectric constant d33 is not achieved. If the temperature of the heat treatment is higher than 1200° C., there is a probability that the ceramic melts. A more preferred range of the heat treatment temperature is not less than 600° C. and not more than 1100° C. The treatment duration is preferably not less than 0.5 hour and not more than 24 hours. If the treatment duration is shorter than 0.5 hour, the above-described complementation with oxygen is insufficient, so that there is a probability that a sufficiently high piezoelectric constant d33 is not achieved. If the treatment duration is longer than 24 hours, part of the elements which are constituents of the piezoelectric ceramic volatilize in some cases. A more preferred range of the treatment duration is not less than 1 hour and not more than 10 hours.

The ceramic manufactured through the above-described steps can exhibit excellent piezoelectric characteristics. However, to actually achieve expression of the piezoelectric characteristics, electrodes are formed and a polarization treatment is carried out such that uniform orientation of spontaneous polarization is achieved in the ceramic. The polarization treatment may be a known polarization treatment which is commonly employed for manufacture of piezoelectric ceramics. For example, a sintered body on which electrodes are formed is maintained at a temperature which is not less than the room temperature and not more than 200° C. by using a silicone bath, and a voltage of about not less than 0.5 kV/mm and not more than 6 kV/mm is applied across the sintered body. As a result, a piezoelectric ceramic which has piezoelectric characteristics can be obtained.

Thus, according to the present embodiment, sintering in a reducing atmosphere can be employed. A lead-free piezoelectric ceramic can be realized which has excellent piezoelectric characteristics as compared with a case where the sintering is carried out in the air as in the conventional methods. Particularly, according to the present embodiment, a piezoelectric ceramic can be realized which has a large piezoelectric constant d33 and a high Curie temperature as compared with a case where the sintering is carried out in the air. Specifically, in the case of a piezoelectric ceramic which has a composition of Formula (1), the piezoelectric constant d33 of the piezoelectric ceramic can be not less than 250 pC/N so long as s is in the range of 0.065≦s≦0.10.

In the case of a piezoelectric ceramic which has a composition of Formula (2), the piezoelectric constant d33 of the piezoelectric ceramic can be not less than 270 pC/N so long as s is in the range of 0.065≦s≦0.10 and t is in the range of 0.005<t≦0.015. The piezoelectric constant d33 of the piezoelectric ceramic can be not less than 300 pC/N so long as s is in the range of 0.075≦s≦0.95 and t is in the range of 0.005≦t≦0.015.

The piezoelectric ceramic of the present embodiment is suitably applicable to a piezoelectric ceramic and a piezoelectric element including a plurality of internal electrodes which are in contact with a piezoelectric ceramic. The piezoelectric element may include a pair of electrodes which are arranged so as to sandwich a piezoelectric ceramic or may include a plurality of electrodes which are arranged inside via a piezoelectric ceramic. In this case, the piezoelectric ceramic can be formed in a reducing atmosphere, and therefore, the electrodes can be formed using, for example, a paste which contains a base metal element that is likely to oxidize at relatively high temperatures.

### EXAMPLES

Piezoelectric ceramics of various compositions were manufactured according to the method for manufacturing piezoelectric ceramic of the present embodiment, and the characteristics of the manufactured piezoelectric ceramics were evaluated. Hereinafter, the results of the evaluation are described.

### 1. Examples 1 to 8, Comparative Examples 1 to 5, Reference Examples 1A to 6A, Reference Examples 1AH to 4AH, Reference Examples 1B to 6B, Reference Examples 1BH to 4BH

(1) Manufacture of Piezoelectric Ceramic

Piezoelectric ceramics of Examples 1 to 8, Comparative Examples 1 to 5, Reference Examples 1A to 6A, Reference Examples 1AH to 4AH, Reference Examples 1B to 6B, and Reference Examples 1BH to 4BH were manufactured as described below.

### Example 1

A piezoelectric ceramic was manufactured in which s=0.08 in (1-s)ABO₃-sBaZrO₃ represented by Formula (1).

K₂CO₃, Na₂CO₃, Li₂CO₃, and Nb₂O₅ were weighed such that K, Na, Li and Nb were in a composition ratio represented by (K_{0.45}Na_{0.5}Li_{0.05})NbO₃ as the alkali metal-containing niobium oxide-based composition (hereinafter, “alkali-niobium raw materials”).

BaCO₃ and ZrO₂ were weighed and added to the alkali-niobium raw materials such that the composition after the sintering was 0.92(K_{0.45}Na_{0.5}Li_{0.05})NbO₃-0.08BaZrO₃.

These raw materials were mixed together by a ball mill. The solvent used was ethanol. The media used was zirconia balls. The mixing was carried out at 94 rpm for 24 hours. The media and raw materials were pulled out from the container of the ball mill, and the raw materials were separated by a sieve from the media. Thereafter, the raw materials were dried in the air at 130° C. (Step 1).

The dried raw material mixture powder was press-molded into the shape of a disk and presintered by the step of keeping it in the air at 1050° C. for 3 hours. The compressed, presintered powder was crushed into a powder form using a triturator, or the like, and mixed at 94 rpm for 24 hours with the use of ethanol as the solvent and zirconia balls as the media. After being mixed, the raw materials were separated by a sieve from the media and dried in the air at 130° C., whereby presintered powder was obtained.

The resultant presintered powder was press-molded into the shape of a disk with a diameter of 13 mm and a thickness of 1.0 mm (Step 2).

The resultant molded body was subjected to reductive sintering according to the temperature profile and atmosphere illustrated in FIG. 2. Specifically, the molded body was kept at 1100° C. for 4 hours in a N₂-2% H₂ atmosphere which had an oxygen partial pressure of 1×10⁻⁹ kPa and which was at the atmospheric pressure, whereby the molded body was sintered, and then cooled to the room temperature (Step 3).

Thereafter, the sintered body was kept at 1000° C. for 3 hours in a N₂ atmosphere which had an oxygen partial pressure of 2×10⁻³ kPa (oxygen concentration: about 20 ppm) and which was at the atmospheric pressure, whereby the recovery heat treatment was carried out (Step 4).

Electrodes were formed on the resultant sintered body, and a voltage of 4000 V/mm was applied across the sintered body in a silicone oil at 150° C., whereby the polarization treatment was carried out. As a result, a piezoelectric ceramic having a composition of 0.92(K_{0.45}Na_{0.5}Li_{0.05})NbO₃-0.08BaZrO₃ was obtained.

### Example 2

A piezoelectric ceramic having a composition where s=0.07 in Formula (1), i.e., 0.93(K_{0.45}Na_{0.5}Li_{0.05})NbO₃-0.07BaZrO₃, was manufactured by the same method as that employed for Example 1 except for the difference in composition.

### Example 3

A piezoelectric ceramic having a composition where s=0.09 and t=0.01 in (1-s−t)ABO₃-sBaZrO₃-t(R.M)TiO₃ represented by Formula (2) was manufactured.

K₂CO₃, Na₂CO₃, Li₂CO₃ and Nb₂O₅ were weighed such that K, Na, Li and Nb were in a composition ratio represented by (K_{0.45}Na_{0.5}Li_{0.05})NbO₃ as the alkali metal-containing niobium oxide-based composition (alkali-niobium raw materials).

BaCO₃, ZrO₂, La₂O₃, Na₂CO₃ and TiO₂ were weighed and added to the alkali-niobium raw materials such that the composition after the sintering was 0.90(K_{0.45}Na_{0.5}Li_{0.05})NbO₃-0.09BaZrO₃-0.01(La_{0.5}Na_{0.5})TiO₃.

Thereafter, a piezoelectric ceramic having a composition of 0.90(K_{0.45}Na_{0.5}Li_{0.05})NbO₃-0.09BaZrO₃-0.01(La_{0.5}Na_{0.5})TiO₃ was manufactured through the same procedure as that employed for Example 1.

### Example 4

A piezoelectric ceramic having a composition where s=0.11 and t=0.01 in (1-s−t)ABO₃-sBaZrO₃-t(R.M)TiO₃ represented by Formula (2), i.e., 0.88(K_{0.45}Na_{0.5}Li_{0.05})NbO₃-0.11BaZrO₃-0.01(La_{0.5}Na_{0.5})TiO₃, was manufactured through the same procedure as that employed for Example 3 except for the difference in composition ratio.

### Example 5

A piezoelectric ceramic having a composition where s=0.13 and t=0.01 in (1-s−t)ABO₃-sBaZrO₃-t(R.M)TiO₃ represented by Formula (2), i.e., 0.86(K_{0.45}Na_{0.5}Li_{0.05})NbO₃-0.13BaZrO₃-0.01(La_{0.5}Na_{0.5})TiO₃, was manufactured through the same procedure as that employed for Example 3 except for the difference in composition ratio.

### Example 6

A piezoelectric ceramic having a composition where s=0.07 and t=0.01 in (1-s−t)ABO₃-sBaZr₃-t(R.M)TiO₃ represented by Formula (2), i.e., 0.92(K_{0.45}Na_{0.5}Li_{0.05})NbO₃-0.07BaZrO₃-0.01(La_{0.5}Na_{0.5})TiO₃, was manufactured through the same procedure as that employed for Example 3 except for the difference in composition ratio.

### Example 7

A piezoelectric ceramic having a composition of 0.92(K_{0.45}Na_{0.5}Li_{0.05})NbO₃-0.08BaZrO₃ was manufactured through the same procedure as that employed for Example 1 (s=0.08, t=0) except that the recovery heat treatment was carried out in the air.

### Example 8

A piezoelectric ceramic having a composition of 0.90(K_{0.45}Na_{0.5}Li_{0.05})NbO₃-0.09BaZrO₃-0.01 (La_{0.5}Na_{0.5})TiO₃ was manufactured through the same procedure as that employed for Example 3 (s=0.09, t=0.01) except that the recovery heat treatment was carried out in the air.

### Comparative Example 1

A piezoelectric ceramic having a composition where s=0.06 in Formula (1), i.e., 0.94(K_{0.45}Na_{0.5}Li_{0.05})NbO₃-0.06BaZrO₃, was manufactured by the same method as that employed for Example 1 except for the difference in composition. Note that, however, at the polarization treatment step, the resistance of the ceramic was not more than 1 MΩ·cm so that conduction occurred, and the polarization treatment was not successfully carried out.

### Comparative Example 2

A piezoelectric ceramic in which s=0 in Formula (1) and which had a composition of (K_{0.49}Na_{0.49}Li_{0.2})(Nb_{0.8}Ta_{0.2})O₃ was manufactured through the same procedure as that employed for Example 1.

### Comparative Example 3

A piezoelectric ceramic in which s=0 in Formula (1) and which had a composition of (K_{0.48}Na_{0.48}Li_{0.4})(Nb_{0.8}Ta_{0.2})O₃ was manufactured through the same procedure as that employed for Example 1.

### Comparative Example 4

A ceramic having a composition where s=0.05 and t=0.01 in (1-s−t)ABO₃-sBaZrO₃-t(R.M)TiO₃ represented by Formula (2), i.e., 0.94(K_{0.45}Na_{0.5}Li_{0.05})NbO₃-0.05BaZrO₃-0.01(La_{0.5}Na_{0.5})TiO₃, was manufactured through the same procedure as that employed for Example 3 except for the difference in composition ratio. Note that, however, at the polarization treatment step, the resistance of the ceramic was not more than 1 MΩ·cm so that conduction occurred, and the polarization treatment was not successfully carried out.

### Comparative Example 5

A ceramic of Comparative Example 5 was manufactured with the intention of manufacturing a ceramic which had a composition where s=0.05 and t=0.01, and Bi was used in place of R, in (1-s−t)ABO₃-sBaZrO₃-t(R.M)TiO₃ represented by Formula (2). K₂CO₃, Na₂CO₃, Li₂CO₃ and Nb₂O₅ were weighed such that K, Na, Li and Nb constitute a composition of (K_{0.45}Na_{0.5}Li_{0.05})NbO₃ as the alkali metal-containing niobium oxide-based composition (alkali-niobium raw materials).

BaCO₃, ZrO₂, Bi₂O₃, Na₂CO₃ and TiO₂ were weighed and added to the alkali-niobium raw materials such that the composition after the sintering was 0.94(K_{0.45}Na_{0.5}Li_{0.05})NbO₃-0.05BaZrO₃-0.01(Bi_{0.5}Na_{0.5})TiO₃.

Thereafter, a ceramic was manufactured through the same procedure as that employed for Example 1.

### Reference Examples 1A to 6A, Reference Examples 1AH to 4AH

Ceramics were manufactured using raw materials which had the same compositions as those used for Examples 1 to 6 and Comparative Examples 1 to 4. In the manufacture, only the reductive sintering step was carried out while the recovery heat treatment was not carried out. The manufactured ceramics are labeled as Reference Examples 1A to 6A and Reference Examples 1AH to 4AH.

### Reference Examples 1B to 6B, Reference Examples 1BH to 4BH

Ceramics were manufactured using raw materials which had the same compositions as those used for Examples 1 to 6 and Comparative Examples 1 to 4. In the manufacture, only a sintering step was carried out in such a manner that a molded body was kept in the air at 1200° C. for 4 hours, instead of the reductive sintering, while the recovery heat treatment was not carried out. The manufactured ceramics are labeled as Reference Examples 1B to 6B and Reference Examples 1BH to 4BH.

(2) Measurement of Characteristics

The piezoelectric constant d33 and Curie temperature of the manufactured ceramics were measured. The piezoelectric constant d33 was measured using a ZJ-6B d33 meter (manufactured by the Chinese Academy of Sciences). The Curie temperature was measured by an impedance analyzer. Specifically, the temperature dependence of the relative permittivity was measured, and a temperature at which the maximum relative permittivity was achieved was recognized as the Curie temperature. A ceramic which was provided with a thermocouple and terminals was inserted into a small tube furnace (quartz tube), and the temperature and capacitance were measured using a YHP4194A impedance analyzer (manufactured by Hewlett-Packard).

Meanwhile, cross-sectional SEM photographs of the manufactured ceramics were obtained. An arbitrary line was drawn on a SEM photograph, and 10 crystals on the line were arbitrarily selected. The maximum diameters of the selected crystals were measured, and the average crystal grain diameter was determined.

As for the ceramic of Comparative Example 5, only an elemental analysis by EPMA was carried out as will be described later.

(3) Results and Consideration

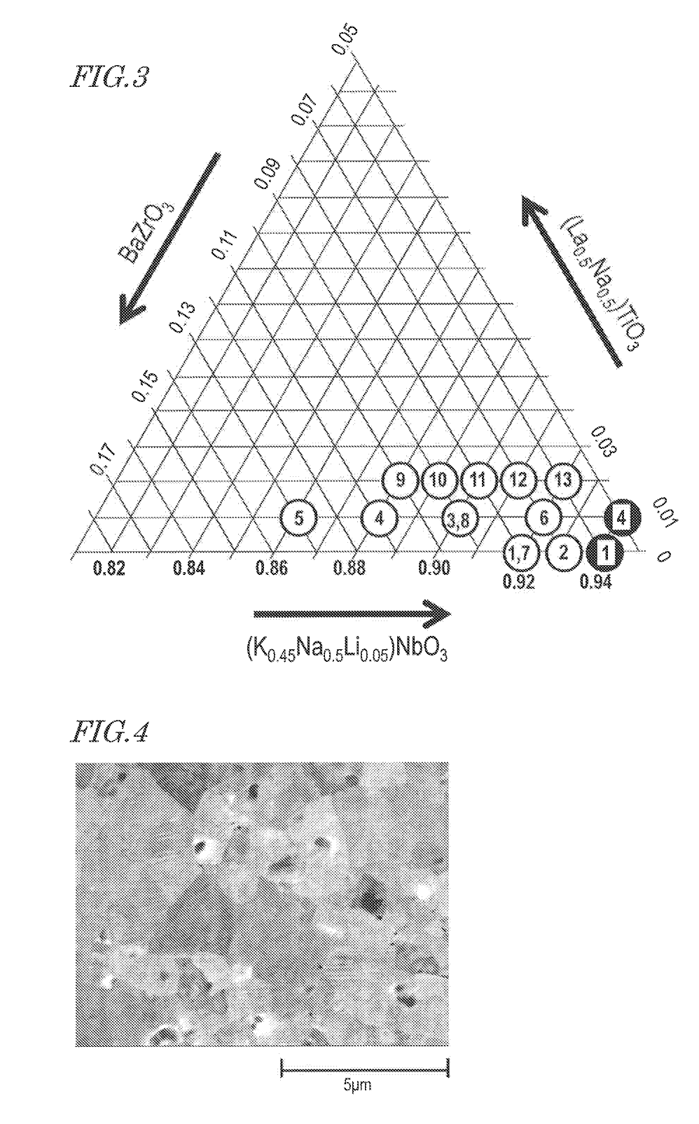

FIG. 3 shows the mixture ratio of (K_{0.45}Na_{0.5}Li_{0.05})NbO₃, BaZrO₃, and (La_{0.5}Na_{0.5})TiO₃ in the manufactured ceramics of Examples 1 to 8 and Comparative Examples 1 and 4. In the diagram, open circles represent Examples, and solid circles represent Comparative Examples. The numerals in the circles correspond to the numbers of Examples 1 to 8 and Comparative Examples 1 and 4.

Table 1 shows the composition ratio of the manufactured ceramics of Examples 1 to 8 and Comparative Examples 1 to 4, and the measured piezoelectric constant d33, average crystal grain diameter and Curie temperature.

Table 2 shows the composition ratio of the manufactured ceramics of Reference Examples 1A to 6A and Reference Examples 1AH to 4AH (ceramics not subjected to the recovery heat treatment), and the measured piezoelectric constant d33, average crystal grain diameter and Curie temperature.

Table 3 shows the composition ratio of the manufactured ceramics of Reference Examples 1B to 6B and Reference Examples 1BH to 4BH (ceramics sintered in the air and not subjected to the recovery heat treatment), and the measured piezoelectric constant d33, average crystal grain diameter and Curie temperature.

In Table 1 through Table 3, “-” in the column of the piezoelectric constant means failure of measurement which was attributed to failure of the polarization treatment. In the column of the Curie temperature, “-” means failure to define the Curie temperature for the reason that the piezoelectric characteristics were not exhibited. In the column of the average crystal grain diameter, “-” means failure to measure the average crystal grain for the reason that the contours of the crystal grains were blurred. Table 1 also shows the ratio of the piezoelectric constant d33 of the ceramics of Examples 1 to 8 and Comparative Examples 1 and 4 to the piezoelectric constant d33 of the ceramics of Reference Examples 1B to 6B and Reference Examples 1BH to 4BH.

TABLE 1

| | | Piezoelectric | Average Crystal | Curie | Piezoelectric |
|---|---|---|---|---|---|
| | | Constant | Grain Diameter | Temperature | Constant |
| Sample | Composition | d33 (pC/N) | (μm) | (° C.) | Ratio |
| Example 1 | 0.92(K_{0.45}Na_{0.5}Li_{0.05})NbO₃—0.08BaZrO₃ | 295 | 1.8 | 240 | 1.92 |
| Example 2 | 0.93(K_{0.45}Na_{0.5}Li_{0.05})NbO₃—0.07BaZrO₃ | 250 | 2.0 | 240 | 1.15 |
| Comparative | 0.94(K_{0.45}Na_{0.5}Li_{0.05})NbO₃—0.06BaZrO₃ | — | 2.0 | 230 | — |
| Example 1 | | | | | |
| Comparative | (K_{0.49}Na_{0.49}Li_{0.2})(Nb_{0.8}Ta_{0.2})O₃ | 170 | 3.1 | 300 | 0.88 |
| Example 2 | | | | | |
| Comparative | (K_{0.48}Na_{0.48}Li_{0.4})(Nb_{0.8}Ta_{0.2})O₃ | 210 | 3.1 | 300 | 0.76 |
| Example 3 | | | | | |
| Example 3 | 0.90(K_{0.45}Na_{0.5}Li_{0.05})NbO₃—0.09BaZrO₃—0.01(La_{0.5}Na_{0.5})TiO₃ | 330 | 1.8 | 180 | 2.92 |
| Example 4 | 0.88(K_{0.45}Na_{0.5}Li_{0.05})NbO₃—0.11BaZrO₃—0.01(La_{0.5}Na_{0.5})TiO₃ | 140 | 1.7 | 200 | 2.59 |
| Example 5 | 0.86(K_{0.45}Na_{0.5}Li_{0.05})NbO₃—0.13BaZrO₃—0.01(La_{0.5}Na_{0.5})TiO₃ | 43 | 1.8 | 120 | 1.39 |
| Example 6 | 0.92(K_{0.45}Na_{0.5}Li_{0.05})NbO₃—0.07BaZrO₃—0.01(La_{0.5}Na_{0.5})TiO₃ | 278 | 1.7 | 250 | (1<) |
| Comparative | 0.94(K_{0.45}Na_{0.5}Li_{0.05})NbO₃—0.05BaZrO₃—0.01(La_{0.5}Na_{0.5})TiO₃ | — | 1.6 | — | — |
| Example 4 | | | | | |
| Example 7 | 0.92(K_{0.45}Na_{0.5}Li_{0.05})NbO₃—0.08BaZrO₃ | 340 | 1.6 | 250 | 3.01 |
| Example 8 | 0.90(K_{0.45}Na_{0.5}Li_{0.05})NbO₃—0.09BaZrO₃—0.01(La_{0.5}Na_{0.5})TiO₃ | 340 | 1.6 | 190 | 6.03 |

TABLE 2

| | | Piezoelectric | Average Crystal | Curie |
|---|---|---|---|---|
| | | Constant | Grain Diameter | Temperature |
| Sample | Composition | d33 (pC/N) | (μm) | (° C.) |
| Reference 1A | 0.92(K_{0.45}Na_{0.5}Li_{0.05})NbO₃—0.08BaZrO₃ | — | 1.6 | — |
| Reference 2A | 0.93(K_{0.45}Na_{0.5}Li_{0.05})NbO₃—0.07BaZrO₃ | — | 1.8 | — |
| Reference 1AH | 0.94(K_{0.45}Na_{0.5}Li_{0.05})NbO₃—0.06BaZrO₃ | — | 1.7 | — |
| Reference 2AH | (K_{0.49}Na_{0.49}Li_{0.2})(Nb_{0.8}Ta_{0.2})O₃ | — | 3.1 | — |
| Reference 3AH | (K_{0.48}Na_{0.48}Li_{0.4})(Nb_{0.8}Ta_{0.2})O₃ | — | 3.1 | — |
| Reference 3A | 0.90(K_{0.45}Na_{0.5}Li_{0.05})NbO₃—0.09BaZrO₃—0.01(La_{0.5}Na_{0.5})TiO₃ | — | 1.7 | — |
| Reference 4A | 0.88(K_{0.45}Na_{0.5}Li_{0.05})NbO₃—0.11BaZrO₃—0.01(La_{0.5}Na_{0.5})TiO₃ | — | 1.6 | — |
| Reference 5A | 0.86(K_{0.45}Na_{0.5}Li_{0.05})NbO₃—0.13BaZrO₃—0.01(La_{0.5}Na_{0.5})TiO₃ | — | 1.8 | — |
| Reference 6A | 0.92(K_{0.45}Na_{0.5}Li_{0.05})NbO₃—0.07BaZrO₃—0.01(La_{0.5}Na_{0.5})TiO₃ | — | 1.7 | — |
| Reference 4AH | 0.94(K_{0.45}Na_{0.5}Li_{0.05})NbO₃—0.05BaZrO₃—0.01(La_{0.5}Na_{0.5})TiO₃ | — | 1.6 | — |

TABLE 3

| | | Piezoelectric | Average Crystal | Curie |
|---|---|---|---|---|
| | | Constant | Grain Diameter | Temperature |
| Sample | Composition | d33 (pC/N) | (μm) | (° C.) |
| Reference 1B | 0.92(K_{0.45}Na_{0.5}Li_{0.05})NbO₃—0.08BaZrO₃ | 154 | — | 230 |
| Reference 2B | 0.93(K_{0.45}Na_{0.5}Li_{0.05})NbO₃—0.07BaZrO₃ | 218 | — | 220 |
| Reference 1BH | 0.94(K_{0.45}Na_{0.5}Li_{0.05})NbO₃—0.06BaZrO₃ | 225 | — | 200 |
| Reference 2BH | (K_{0.49}Na_{0.49}Li_{0.2})(Nb_{0.8}Ta_{0.2})O₃ | 193 | 3 | 300 |
| Reference 3BH | (K_{0.48}Na_{0.48}Li_{0.4})(Nb_{0.8}Ta_{0.2})O₃ | 276 | 3 | 300 |
| Reference 3B | 0.90(K_{0.45}Na_{0.5}Li_{0.05})NbO₃—0.09BaZrO₃—0.01(La_{0.5}Na_{0.5})TiO₃ | 113 | — | 170 |
| Reference 4B | 0.88(K_{0.45}Na_{0.5}Li_{0.05})NbO₃—0.11BaZrO₃—0.01(La_{0.5}Na_{0.5})TiO₃ | 54 | — | 180 |
| Reference 5B | 0.86(K_{0.45}Na_{0.5}Li_{0.05})NbO₃—0.13BaZrO₃—0.01(La_{0.5}Na_{0.5})TiO₃ | 31 | — | 100 |
| Reference 6B | 0.92(K_{0.45}Na_{0.5}Li_{0.05})NbO₃—0.07BaZrO₃—0.01(La_{0.5}Na_{0.5})TiO₃ | — | 1.8 | 200 |
| Reference 4BH | 0.94(K_{0.45}Na_{0.5}Li_{0.05})NbO₃—0.05BaZrO₃—0.01(La_{0.5}Na_{0.5})TiO₃ | — | 1.5 | — |

As seen from comparison of the characteristic values of Examples 1 and 2 and Comparative Example 1 shown in Table 1, a ceramic which exhibits piezoelectric characteristics can be obtained when s is greater than 0.06 in the composition represented by Formula (1).

As seen from comparison of Examples 1 and 2 of Table 1 and Reference Examples 1B and 2B of Table 3, the examples of the present invention represented by Formula (1) enable to obtain a piezoelectric ceramic which has a large piezoelectric constant d33 and a high Curie temperature as compared with a case where the sintering is carried out in the air. In the ceramics of the examples of the present invention, the piezoelectric constant d33 is greater by 10% or more.

FIG. 4 shows an example of a SEM photograph of the ceramic of Example 1. As seen from FIG. 4, definite crystal grains were recognized, and the average crystal grain diameter was 1.8 μm. On the other hand, in the ceramic of Reference Example 1B that was sintered in the air, definite crystal grains were not recognized. It is inferred that formation of such crystal grains contributes to improvement in characteristics as to the piezoelectric constant d33 and the Curie temperature.

Likewise, as seen from comparison of the characteristic values of Examples 3 to 6 and Comparative Example 4 shown in Table 1, a ceramic which exhibits piezoelectric characteristics can be obtained when s is greater than 0.05 in the composition represented by Formula (2).

As seen from comparison of Examples 3 to 5 of Table 1 and Reference Examples 3B to 5B of Table 3, the examples of the present invention represented by Formula (2) enable to obtain a piezoelectric ceramic which has a large piezoelectric constant d33 and a high Curie temperature as compared with a case where the sintering is carried out in the air. In the ceramics of the examples of the present invention, the piezoelectric constant d33 is greater by 10% or more, and the Curie temperature is higher by 10° C. or more. Particularly in Examples 3 and 4, the piezoelectric constant d33 is twice or more that of corresponding reference examples.

As for Example 6, the piezoelectric constant ratio could not be converted to a numerical value because electrical conduction occurred in the ceramic of Reference Example 6B so that the piezoelectric constant d33 could not be measured. However, it is obvious that the piezoelectric constant d33 of Example 6, 278 pC/N, is greater than that of Reference Example 6B, and the piezoelectric constant ratio exceeds 1 (1<).

It was found from comparison of Table 1 and Table 2 that, even in the case where a ceramic is manufactured using a starting material which has the same composition as that of the example of the present invention through the same procedure as that employed for the example of the present invention, if only the reductive sintering is performed while the recovery heat treatment is not performed, a resultant ceramic has electrical conductivity so that the polarization treatment cannot be performed, and therefore, a piezoelectric ceramic which exhibits piezoelectric characteristics cannot be obtained. This is probably because a ceramic obtained by the reductive sintering has oxygen vacancies and therefore has electrical conductivity, and the ceramic is complemented with oxygen at the recovery heat treatment step and therefore has an insulation property.

In Examples 7 and 8, the recovery heat treatment was carried out in the air. Examples 7 and 8 have the same compositions as those of Examples 1 and 3, respectively, which were subjected to the recovery heat treatment at the oxygen partial pressure of 2×10⁻³ kPa. The difference in piezoelectric constant d33 between Example 1 and Example 7 is 45. The difference in piezoelectric constant d33 between Example 3 and Example 8 is 10. It can be seen from this that inclusion of (La_{0.5}Na_{0.5})TiO₃ enables to obtain a piezoelectric ceramic which exhibits a still higher piezoelectric constant d33 even when the recovery heat treatment is carried out at a low oxygen partial pressure. That is, a piezoelectric ceramic which has a composition represented by Formula (2) can achieve a high piezoelectric constant d33 while suppressing oxidation of electrodes during the recovery heat treatment. Therefore, it can be more suitably used for a piezoelectric element including an internal electrode which is made of a base metal.

As seen from comparison of Examples 1 to 8 of Table 1 and Reference Examples 1A to 6A of Table 2, the ceramics of Examples 1 to 8 have greater average crystal grain diameters than the ceramics of Reference Examples 1A to 6A although the ceramics of Reference Examples 1A to 6A do not exhibit piezoelectric characteristics. This is probably because, as previously described, oxygen defects were produced during the sintering because of the reductive sintering so that a spatial margin was given in the ceramic, and this margin enhances crystallization so that the crystal grain size increases. As for the ceramics sintered in the air, measurement of the average crystal grain failed because the contours of the crystal grains were blurred.

The ceramic of Comparative Example 5 did not exhibit piezoelectric characteristics. The result of the elemental analysis by EPMA of the ceramic of Comparative Example 5 is shown in Table 4. As seen from Table 4, Bi was not detected, and it was found that Bi volatilized. It was found from this that, when Bi is used in substitution for La, Bi volatilizes during the reductive sintering, so that a ceramic of an intended composition cannot be obtained, and the resultant ceramic does not exhibit piezoelectric characteristics.

TABLE 4

| | Bi | Na | Ti | K | Nb | Ba | Zr | O |
|---|---|---|---|---|---|---|---|---|
| Mass % | 0 | 4.3 | 17.9 | 6.9 | 46.3 | 5.5 | 3.8 | 15.3 |

As seen from the foregoing, according to a piezoelectric ceramic and method for manufacturing piezoelectric ceramic of the present invention, inclusion of the compositions represented by Formulae (1) and (2) enables to realize a piezoelectric ceramic which exhibits a high piezoelectric constant d33 and a high Curie temperature as compared with a case where the sintering is carried out in the air. Thus, a piezoelectric element which does not include lead and which includes an internal electrode that is made of a base metal can be suitably realized. Further, since Bi is not used, the sintering can be carried out in a reducing atmosphere.

### 2. Examples 9 to 13

(1) Manufacture of Piezoelectric Ceramic

Piezoelectric ceramics of Examples 9 to 13 were manufactured as described below.

### Example 9

A piezoelectric ceramic having a composition where s=0.10 and t=0.02 in (1-s−t)ABO₃-sBaZrO₃-t(R.M)TiO₃ represented by Formula (2), i.e., 0.88(K_{0.45}Na_{0.5}Li_{0.05})NbO₃-0.10BaZrO₃-0.02(La_{0.5}Na_{0.5})TiO₃, was manufactured through the same procedure as that employed for Example 3 except for the difference in composition ratio.

### Example 10

A piezoelectric ceramic having a composition where s=0.09 and t=0.02 in (1-s−t)ABO₃-sBaZrO₃-t(R.M)TiO₃ represented by Formula (2), i.e., 0.89(K_{0.45}Na_{0.5}Li_{0.05})NbO₃-0.09BaZrO₃-0.02(La_{0.5}Na_{0.5})TiO₃, was manufactured through the same procedure as that employed for Example 3 except for the difference in composition ratio.

### Example 11

A piezoelectric ceramic having a composition where s=0.08 and t=0.02 in (1-s−t)ABO₃-sBaZrO₃-t(R.M)TiO₃ represented by Formula (2), i.e., 0.90(K_{0.45}Na_{0.5}Li_{0.05})NbO₃-0.08BaZrO₃-0.02(La_{0.5}Na_{0.5})TiO₃, was manufactured through the same procedure as that employed for Example 3 except for the difference in composition ratio.

### Example 12

A piezoelectric ceramic having a composition where s=0.07 and t=0.02 in (1-s−t)ABO₃-sBaZrO₃-t(R.M)TiO₃ represented by Formula (2), i.e., 0.91(K_{0.45}Na_{0.5}Li_{0.05})NbO₃-0.07BaZrO₃-0.02(La_{0.5}Na_{0.5})TiO₃, was manufactured through the same procedure as that employed for Example 3 except for the difference in composition ratio.

### Example 13

A piezoelectric ceramic having a composition where s=0.06 and t=0.02 in (1-s−t)ABO₃-sBaZrO₃-t(R.M)TiO₃ represented by Formula (2), i.e., 0.92(K_{0.45}Na_{0.5}Li_{0.05})NbO₃-0.06BaZrO₃-0.02(La_{0.5}Na_{0.5})TiO₃, was manufactured through the same procedure as that employed for Example 3 except for the difference in composition ratio.

(2) Measurement of Characteristics

The piezoelectric constant d33 and Curie temperature of the manufactured ceramics were measured through the same procedure as that employed for Examples 1 to 8.

(3) Results and Consideration

FIG. 3 shows the mixture ratio of (K_{0.45}Na_{0.5}Li_{0.05})NbO_{3,} BaZrO₃ and (La_{0.5}Na_{0.5})TiO₃ in the manufactured ceramics of Examples 9 to 13. In the diagram, open circles represent Examples, and the numerals in the circles correspond to Examples 9 to 13. Table 5 shows the composition ratio of the manufactured ceramics of Examples 9 to 13, and the measured piezoelectric constant d33, Curie temperature, and piezoelectric constant ratio.

As seen from Table 5, even when t was 0.02 in the composition represented by Formula (2), a piezoelectric ceramic having a large piezoelectric constant d33 was obtained as in Examples 1 to 8. The ratios of d33 of the ceramics of Examples 9 to 13 for which the manufacturing method of the present invention was employed to d33 of the piezoelectric ceramic on which only the sintering was carried out in the air are all more than 1. A piezoelectric ceramic which had a greater piezoelectric constant d33 than that manufactured by the conventional manufacturing method was obtained.

TABLE 5

| | | Piezoelectric | Curie | Piezoelectric |
|---|---|---|---|---|
| | | Constant | Temperature | Constant |
| Sample | Composition | d33 (pC/N) | (° C.) | Ration |
| Example 9 | 0.88(K_{0.45}Na_{0.5}Li_{0.05})NbO₃—0.10BaZrO₃—0.02(La_{0.5}Na_{0.5})TiO₃ | 265 | 152 | 3.01 |
| Example 10 | 0.89(K_{0.45}Na_{0.5}Li_{0.05})NbO₃—0.09BaZrO₃—0.02(La_{0.5}Na_{0.5})TiO₃ | 280 | 190 | (1<) |
| Example 11 | 0.90(K_{0.45}Na_{0.5}Li_{0.05})NbO₃—0.08BaZrO₃—0.02(La_{0.5}Na_{0.5})TiO₃ | 251 | 223 | (1<) |
| Example 12 | 0.91(K_{0.45}Na_{0.5}Li_{0.05})NbO₃—0.07BaZrO₃—0.02(La_{0.5}Na_{0.5})TiO₃ | 275 | 246 | 2.67 |
| Example 13 | 0.92(K_{0.45}Na_{0.5}Li_{0.05})NbO₃—0.06BaZrO₃—0.02(La_{0.5}Na_{0.5})TiO₃ | 262 | 271 | 2.38 |

### 3. Example 14

Piezoelectric ceramics were manufactured with varying sintering durations, and the characteristics of the manufactured piezoelectric ceramics were measured.

(1) Manufacture of Piezoelectric Ceramic

A piezoelectric ceramic having a composition where s=0.09 and t=0.01 in (1-s−t)ABO₃-sBaZrO₃-t(R.M)TiO₃ represented by Formula (2) was manufactured.

K₂CO₃, Na₂CO₃, Li₂CO₃ and Nb₂O₅ were weighed such that K, Na, Li and Nb were in a composition ratio represented by (K_{0.45}Na_{0.5}Li_{0.05})NbO₃ as the alkali metal-containing niobium oxide-based composition (alkali-niobium raw materials).

BaCO₃, ZrO₂, La₂O₃, Na₂CO₃ and TiO₂ were weighed and added to the alkali-niobium raw materials such that the composition after the sintering was 0.90(K_{0.45}Na_{0.5}Li_{0.05})NbO₃-0.09BaZrO₃-0.01(La_{0.5}Na_{0.5})TiO₃.

These raw materials were mixed together by a ball mill. The solvent used was ethanol. The media used was zirconia balls. The mixing was carried out at 94 rpm for 24 hours. The media and raw materials were pulled out from the container of the ball mill, and the raw materials were separated by a sieve from the media. Thereafter, the raw materials were dried in the air at 130° C. (Step 1).

The dried raw material mixture powder was press-molded into the shape of a disk and presintered by the step of keeping it in the air at 1050° C. for 3 hours. The compressed, presintered powder was crushed into a powder form using a triturator, or the like, and mixed at 94 rpm for 24 hours with the use of ethanol as the solvent and zirconia balls as the media. After being mixed, the raw materials were separated by a sieve from the media and dried in the air at 130° C., whereby presintered powder was obtained.

The resultant presintered powder was press-molded into the shape of a disk with a diameter of 13 mm and a thickness of 1.0 mm (Step 2).

The resultant molded body was subjected to reductive sintering according to the temperature profile and atmosphere illustrated in FIG. 2. Specifically, the molded body was sintered at 1200° C. in a N₂-2% H₂ atmosphere which had an oxygen partial pressure of 1×10⁻⁹ kPa and which was at the atmospheric pressure with varying retention times, 2 hours, 4 hours, 8 hours, and 24 hours, and then cooled to the room temperature (Step 3).

Thereafter, the sintered body was kept at 1000° C. for 3 hours in a N₂ atmosphere which had an oxygen partial pressure of 2×10⁻³ kPa (oxygen concentration: about 20 ppm) and which was at the atmospheric pressure, whereby the recovery heat treatment was carried out (Step 4).

Electrodes were formed on the resultant sintered body, and a voltage of 4000 V/mm was applied across the sintered body in a silicone oil at 150° C., whereby the polarization treatment was carried out. As a result, a piezoelectric ceramic was obtained.

(2) Measurement of Characteristics

The piezoelectric constant d33 and Curie temperature of the manufactured ceramics were measured through the same procedure as that employed for Examples 1 to 8.

(3) Results and Consideration

The ceramics manufactured on the conditions that the sintering duration was 2 hours, 4 hours, or 8 hours all have excellent piezoelectric constants d33 and Curie temperatures. Further, even when the sintering duration was 24 hours, a piezoelectric constant d33 of not less than 200 was obtained.

TABLE 6

| | Sintering | Piezoelectric | Curie |
|---|---|---|---|
| | Duration | Constant | Temperature |
| Composition (same as Example 3) | (h) | d33 (pC/N) | (° C.) |
| 0.90(K_{0.45}Na_{0.5}Li_{0.05})NbO₃—0.09BaZrO₃—0.01(La_{0.5}Na_{0.5})TiO₃ | 2 | 290 | 200 |
| | 4 | 330 | 200 |
| | 8 | 300 | 200 |
| | 24 | 205 | 170 |

### 4. Example 15

(1) Manufacture of Piezoelectric Ceramic

A ceramic having a composition where La was used for R in (1-s−t)ABO₃-sBaZrO₃-t(R.M)TiO₃ represented by Formula (2) and a ceramic having a composition where Ce was used for R in (1-s−t)ABO₃-sBaZrO₃-t(R.M)TiO₃ represented by Formula (2) were manufactured and compared in terms of the piezoelectric constant d33 and the electromechanical coupling factor Kp.

K₂CO₃, Na₂CO₃, Li₂CO₃ and Nb₂O₅ were weighed such that K, Na, Li and Nb were in a composition ratio represented by (K_{0.45}Na_{0.5}Li_{0.05})NbO₃ as the alkali metal-containing niobium oxide-based composition (alkali-niobium raw materials).

BaCO₃, ZrO₂, La₂O₃, Na₂CO₃ and TiO₂ were weighed and added to the alkali-niobium raw materials such that the composition after the sintering was (0.99-s)(K_{0.45}Na_{0.5}Li_{0.05})NbO₃-sBaZrO₃-0.01(La_{0.5}Na_{0.5})TiO₃. For this composition where La was used for R, piezoelectric ceramics having compositions where s=0.07, 0.08, 0.085, 0.09, 0.095, 0.1, 0.11, 0.13 and t=0.01 in Formula (2) were manufactured.

BaCO₃, ZrO₂, Ce₂O₃, Na₂CO₃ and TiO₂ were weighed and added to the alkali-niobium raw materials such that the composition after the sintering was (0.99-s)(K_{0.45}Na_{0.5}Li_{0.05})NbO₃-sBaZrO₃-0.01(Ce_{0.5}Na_{0.5})TiO₃. s was varied to 0.05, 0.07, 0.09, 0.11, and 0.13 while t=0.01.

These raw materials were mixed together by a ball mill in the same way as Example 1 (Step 1).

Then, preparation of presintered powder and molding of presintered powder were carried out in the same way as Example 1 (Step 2).

The resultant molded body was kept at 1200° C. for 4 hours in a N₂-2% H₂ atmosphere which had an oxygen partial pressure of 1×10⁻⁹ kPa and which was at the atmospheric pressure, whereby the molded body was sintered, and then cooled to the room temperature (Step 3).

Thereafter, the recovery heat treatment was carried out in the same way as Example 1 (Step 4).

Electrodes were formed on the resultant sintered body, and a voltage of 4000 V/mm was applied across the sintered body in a silicone oil at 150° C., whereby the polarization treatment was carried out. As a result, a piezoelectric ceramic was obtained.

(2) Measurement of Characteristics

The piezoelectric constant d33 and Curie temperature of the manufactured ceramics were measured through the same procedure as that employed for Examples 1 to 8. Further, the resonant frequency (fr) and anti-resonant frequency (fa) were measured using an impedance analyzer (manufactured by HIOKI, Model Number IM3570), and the electromechanical coupling factor Kp was calculated based on the following formula.

1/(kp)²=a(fr/(fa−fr))+b

(where a=0.395, b=0.574)

(3) Results and Consideration

FIG. 5 is a graph showing results where the horizontal axis represents s of Formula (2) (the quantitative ratio of BaZrO₃), and the vertical axis represents the piezoelectric constant d33. Meanwhile, these numerical values are shown in Table 7. In the composition where La is used, the piezoelectric constant d33 is particularly high when s is in the range of 0.08 to 0.10. When s is 0.07, d33 slightly decreases. On the other hand, in the composition where Ce is used, a ceramic in which s is 0.07 has a greater d33 than the other compositions, which is not less than 300 pC/N.

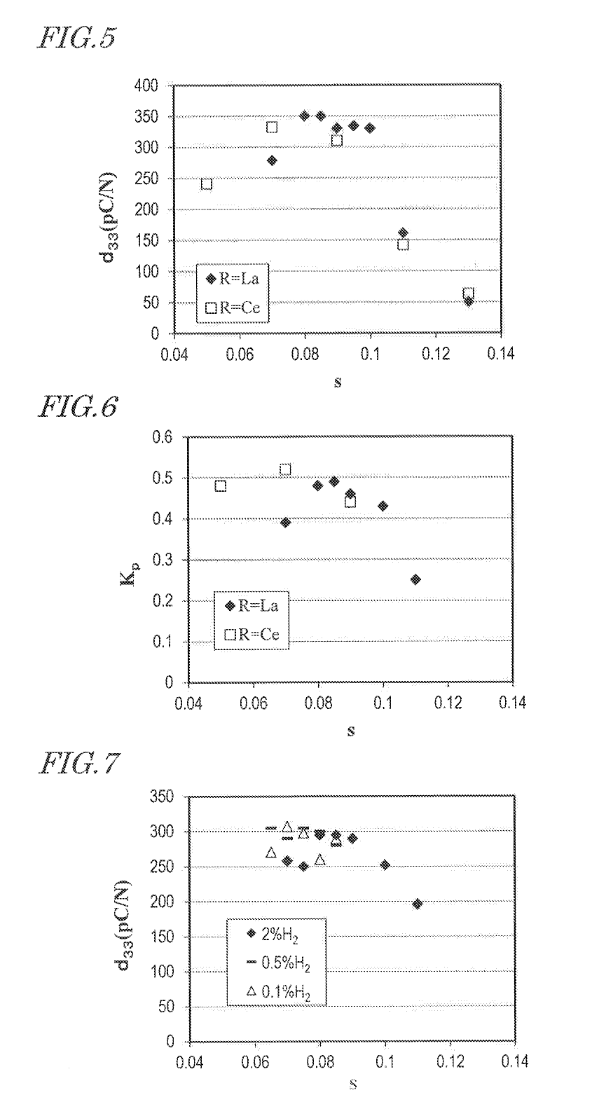

FIG. 6 shows results where the horizontal axis represents s of Formula (2) (the quantitative ratio of BaZrO₃), and the vertical axis represents the electromechanical coupling factor Kp. These numerical values are shown in Table 8. In the composition where La is used, the electromechanical coupling factor Kp is particularly high when s is in the range of 0.08 to 0.10. When s is 0.07, Kp slightly decreases. In the ceramic where Ce is used, when s is 0.07, Kp is greater than those of the other ceramics, which is not less than 300 pC/N.

Considering the largeness of the piezoelectric constant d33 and the electromechanical coupling factor Kp, it is preferred to use a composition where La is used for R when a ceramic of a large d33 is necessary. On the other hand, it can be seen that, when a ceramic of a large Kp is necessary, a composition where Ce is used for R is preferred.

TABLE 7

d33(pC/N)

| s | R = La | R = Ce |
|---|---|---|
| 0.13 | 50 | 63 |
| 0.11 | 161 | 142 |
| 0.1 | 330 | — |
| 0.095 | 334 | — |
| 0.09 | 330 | 310 |
| 0.085 | 350 | — |
| 0.08 | 350 | — |
| 0.07 | 278 | 332 |
| 0.05 | — | 241 |

(—: Not measured)

TABLE 8

Kp

| s | R = La | R = Ce |
|---|---|---|
| 0.13 | — | — |
| 0.11 | 0.25 | — |
| 0.1 | 0.43 | — |
| 0.09 | 0.46 | 0.44 |
| 0.085 | 0.49 | — |
| 0.08 | 0.48 | — |
| 0.07 | 0.39 | 0.52 |
| 0.05 | — | 0.48 |

(—: Not measured)

### 5. Example 16

Ceramics having a composition of (1-s)ABO₃-sBaZrO₃ represented by Formula (1) were manufactured with varying oxygen partial pressures of the reducing atmosphere used in the sintering, and the characteristics of the resultant ceramics were examined.

(1) Manufacture of Piezoelectric Ceramic

K₂CO₃, Na₂CO₃, Li₂CO₃ and Nb₂O₅ were weighed such that K, Na, Li and Nb were in a composition ratio represented by (K_{0.45}Na_{0.5}Li_{0.05})NbO₃ as the alkali metal-containing niobium oxide-based composition (alkali-niobium raw materials).

BaCO₃ and ZrO₂ were weighed and added to the alkali-niobium raw materials such that the composition after the sintering was (1-s) (K_{0.45}Na_{0.5}Li_{0.05})NbO₃-sBaZrO_{3.} In the above formula, s was 0.08.

These raw materials were mixed together by a ball mill in the same way as Example 1 (Step 1).

Then, preparation of presintered powder and molding of presintered powder were carried out in the same way as Example 1 (Step 2).

The resultant molded body was put into a N₂ atmosphere which was at the atmospheric pressure, which contained 0.5% H₂, and which had the oxygen partial pressure varying from 3.9×10⁻¹¹ kPa to 7.0×10⁻⁵ kPa as shown in Table 9. The molded body was sintered in that atmosphere at 1180° C. for 4 hours and then cooled to the room temperature (Step 3).

Thereafter, the recovery heat treatment was carried out in such a manner that the molded body was kept in the air at 1000° C. for 3 hours (Step 4).

Electrodes were formed on the resultant sintered body, and a voltage of 4000 V/mm was applied across the sintered body in a silicone oil at 150° C., whereby the polarization treatment was carried out. As a result, a piezoelectric ceramic was obtained.

(2) Measurement of Characteristics

The piezoelectric constant d33 of the manufactured ceramics was measured through the same procedure as that employed for Examples 1 to 8.

(3) Results and Consideration

Table 9 shows the oxygen partial pressure and the piezoelectric constant d33. A ceramic having a large piezoelectric constant d33 was obtained no matter where in the range of 3.9×10⁻¹¹ kPa to 7.0×10⁻⁵ kPa the oxygen partial pressure was at. Note that, when the sintering is carried out only in the air, the piezoelectric constant d33 is 154 pC/N.

TABLE 9

| | PO₂ | d33 |
|---|---|---|
| Composition | (kPa) | (pC/N) |
| 0.92(K_{0.45}Na_{0.5}Li_{0.05})NbO₃—0.08BaZrO₃ | 3.9 × 10⁻¹¹ | 208 |
| | 1.4 × 10⁻¹⁰ | 280 |
| | 2.3 × 10⁻⁹ | 272 |
| | 5.6 × 10⁻⁸ | 275 |
| | 2.3 × 10⁻⁷ | 276 |
| | 7.0 × 10⁻⁵ | 250 |

### 6. Example 17

Ceramics having a composition of (1-s−t)ABO₃-sBaZrO₃-t(R.M)TiO₃ represented by Formula (2) were manufactured with varying oxygen partial pressures of the reducing atmosphere used in the sintering, and the characteristics of the resultant ceramics were examined.

(1) Manufacture of Piezoelectric Ceramic

K₂CO₃, Na₂CO₃, Li₂CO₃ and Nb₂O₅ were weighed such that K, Na, Li and Nb were in a composition ratio represented by (K_{0.45}Na_{0.5}Li_{0.05})NbO₃ as the alkali metal-containing niobium oxide-based composition (alkali-niobium raw materials).

BaCO₃, ZrO₂, La₂O₃, Na₂CO₃ and TiO₂ were weighed and added to the alkali-niobium raw materials such that the composition after the sintering was (0.99- s)(K_{0.45}Na_{0.5}Li_{0.05})NbO₃-sBaZrO₃-0.01(La_{0.5}Na_{0.5})TiO₃. In the above formula, s was 0.09, and t was 0.01.

These raw materials were mixed together by a ball mill in the same way as Example 1 (Step 1).

Then, preparation of presintered powder and molding of presintered powder were carried out in the same way as Example 1 (Step 2).

The resultant molded body was put into a N₂ atmosphere which was at the atmospheric pressure, which contained 0.5% H₂, and which had the oxygen partial pressure varying from 3.9×10⁻¹¹ kPa to 7.0×10⁻⁵ kPa as shown in Table 10. The molded body was sintered in that atmosphere at 1180° C. for 4 hours and then cooled to the room temperature (Step 3).

Thereafter, the recovery heat treatment was carried out in such a manner that the molded body was kept in the air at 1000° C. for 3 hours (Step 4).

Electrodes were formed on the resultant sintered body, and a voltage of 4000 V/mm was applied across the sintered body in a silicone oil at 150° C., whereby the polarization treatment was carried out. As a result, a piezoelectric ceramic was obtained.

(2) Measurement of Characteristics

The piezoelectric constant d33 of the manufactured ceramics was measured through the same procedure as that employed for Examples 1 to 8.

(3) Results and Consideration

Table 10 shows the oxygen partial pressure and the piezoelectric constant d33. A ceramic having a large piezoelectric constant d33 was obtained no matter where in the range of 3.9×10⁻¹¹ kPa to 7.0×10⁻⁵ kPa the oxygen partial pressure was at. Note that, when the sintering is carried out only in the air, the piezoelectric constant d33 is 113 pC/N.

TABLE 10

| | PO₂ | d33 |
|---|---|---|
| Composition | (kPa) | (pC/N) |
| 0.90(K_{0.45}Na_{0.5}Li_{0.05})NbO₃—0.09BaZrO₃—0.01(La_{0.5}Na_{0.5})TiO₃ | 3.9 × 10⁻¹¹ | 370 |
| | 1.4 × 10⁻¹⁰ | 349 |
| | 2.3 × 10⁻⁹ | 332 |
| | 5.6 × 10⁻⁸ | 324 |
| | 2.3 × 10⁻⁷ | 229 |
| | 7.0 × 10⁻⁵ | 221 |

### 7. Example 18

Ceramics having a composition of (1-s)ABO₃-sBaZrO₃ represented by Formula (1) were manufactured with varying hydrogen concentrations of the reducing atmosphere used in the sintering, and the characteristics of the resultant ceramics were examined.

(1) Manufacture of Piezoelectric Ceramic

K₂CO₃, Na₂CO₃, Li₂CO₃ and Nb₂O₅ were weighed such that K, Na, Li and Nb were in a composition ratio represented by (K_{0.45}Na_{0.5}Li_{0.05})NbO₃ as the alkali metal-containing niobium oxide-based composition (alkali-niobium raw materials).

BaCO₃ and ZrO₂ were weighed and added to the alkali-niobium raw materials such that the composition after the sintering was (1-s)(K_{0.45}Na_{0.5}Li_{0.05})NbO₂-sBaZrO₂. s was varied in the range of 0.065 to 0.11.

These raw materials were mixed together by a ball mill in the same way as Example 1 (Step 1).

Then, preparation of presintered powder and molding of presintered powder were carried out in the same way as Example 1 (Step 2).

The resultant molded body was kept at 1200° C. for 4 hours in a N₂ atmosphere containing 2% H₂ (N₂-2% H₂), a N₂ atmosphere containing 0.5% H₂ (N₂-0.5% H₂), or a N₂ atmosphere containing 0.1% H₂ (N₂-0.1% H₂), which were all at the atmospheric pressure, whereby the molded body was sintered, and then cooled to the room temperature (Step 3).

Thereafter, the recovery heat treatment was carried out in the same way as Example 1 (Step 4).

Electrodes were formed on the resultant sintered body, and a voltage of 4000 V/mm was applied across the sintered body in a silicone oil at 150° C., whereby the polarization treatment was carried out. As a result, a piezoelectric ceramic was obtained.

(2) Measurement of Characteristics

The piezoelectric constant d33 of the manufactured ceramics was measured through the same procedure as that employed for Examples 1 to 8.

(3) Results and Consideration

FIG. 7 shows results where the horizontal axis represents s of Formula (1) (the quantitative ratio of BaZrO₃), and the vertical axis represents the piezoelectric constant d33. Table 11 shows specific numerical values of the results.

It can be seen that, so long as the same composition is achieved (s is constant), ceramics which have generally equal piezoelectric constants d33 can be obtained even when the hydrogen concentration varies.

TABLE 11

| | d33(pC/N) | | |
|---|---|---|---|
| s | 2%H₂ | 0.5%H₂ | 0.1%H₂ |
| 0.11 | 196 | — | — |
| 0.1 | 252 | — | — |
| 0.09 | 290 | — | — |
| 0.085 | 295 | 280 | 290 |
| 0.08 | 295 | 300 | 260 |
| 0.075 | 250 | 305 | 298 |
| 0.07 | 258 | 290 | 307 |
| 0.065 | — | 305 | 270 |

(—: Not measured)

### 8. Example 19

Ceramics having a composition of (1-s−t)ABO₃-sBaZrO₃-t(R.M)TiO₃ represented by Formula (2) were manufactured with varying hydrogen concentrations of the reducing atmosphere used in the sintering, and the characteristics of the resultant ceramics were examined.

(1) Manufacture of Piezoelectric Ceramic

K₂CO₃, Na₂CO₃, Li₂CO₃ and Nb₂O₅ were weighed such that K, Na, Li and Nb were in a composition ratio represented by (K_{0.45}Na_{0.5}Li_{0.05})NbO₃ as the alkali metal-containing niobium oxide-based composition (alkali-niobium raw materials).

BaCO₃, ZrO₂, La₂O₃, Na₂CO₃ and TiO₂ were weighed and added to the alkali-niobium raw materials such that the composition after the sintering was (0.99-s)(K_{0.45}Na_{0.5}Li_{0.05})NbO₃-sBaZrO₃-0.01(La_{0.5}Na_{0.5})TiO₃. s was varied in the range of 0.07 to 0.13.

These raw materials were mixed together by a ball mill in the same way as Example 1 (Step 1).

Then, preparation of presintered powder and molding of presintered powder were carried out in the same way as Example 1 (Step 2).

The resultant molded body was kept at 1200° C. for 4 hours in a N₂ atmosphere containing 2% H₂ (N₂-2% H₂), a N₂ atmosphere containing 0.5% H₂ (N₂-0.5% H₂), or a N₂ atmosphere containing 0.1% H₂ (N₂-0.1% H₂), which were all at the atmospheric pressure, whereby the molded body was sintered, and then cooled to the room temperature (Step 3).

Thereafter, the recovery heat treatment was carried out in the same way as Example 1 (Step 4).

Electrodes were formed on the resultant sintered body, and a voltage of 4000 V/mm was applied across the sintered body in a silicone oil at 150° C., whereby the polarization treatment was carried out. As a result, a piezoelectric ceramic was obtained.

(2) Measurement of Characteristics

The piezoelectric constant d33 and Curie temperature of the manufactured ceramics were measured through the same procedure as that employed for Examples 1 to 8.

(3) Results and Consideration

FIG. 8 is a graph where the horizontal axis represents s of Formula (2) (the quantitative ratio of BaZrO₃), and the vertical axis represents the piezoelectric constant d33. Table 12 shows specific numerical values of the graph.

It can be seen that, so long as the same composition is achieved (s is constant), ceramics which have generally equal piezoelectric constants d33 can be obtained even when the hydrogen concentration varies.

TABLE 12

| | d33(pC/N) | | |
|---|---|---|---|
| s | 2%H₂ | 0.5%H₂ | 0.1%H₂ |
| 0.13 | 50 | — | — |
| 0.11 | 161 | 155 | 142 |
| 0.1 | 330 | 277 | 243 |
| 0.095 | 334 | 250 | 309 |
| 0.09 | 330 | 300 | 280 |
| 0.085 | 350 | 292 | 320 |
| 0.08 | 350 | 277 | 277 |
| 0.075 | — | 280 | 290 |
| 0.07 | 278 | — | — |

(—: Not measured)

### 9. Example 20

Ceramics having a composition of (1-s)ABO₃-sBaZrO₃ represented by Formula (1) were manufactured with different atmospheres used in the recovery heat treatment, and the characteristics of the resultant ceramics were examined.

(1) Manufacture of Piezoelectric Ceramic

K₂CO₃, Na₂CO₃, Li₂CO₃ and Nb₂O₅ were weighed such that K, Na, Li and Nb were in a composition ratio represented by (K_{0.45}Na_{0.5}Li_{0.05})NbO₃ as the alkali metal-containing niobium oxide-based composition (alkali-niobium raw materials).

BaCO₃ and ZrO₂ were weighed and added to the alkali-niobium raw materials such that the composition after the sintering was (1-s)(K_{0.45}Na_{0.5}Li_{0.05})NbO₃-sBaZrO₃. s was varied in the range of 0.07 to 0.13.

These raw materials were mixed together by a ball mill in the same way as Example 1 (Step 1).

Then, preparation of presintered powder and molding of presintered powder were carried out in the same way as Example 1 (Step 2).

The resultant molded body was kept at 1200° C. for 4 hours in a N₂-2% H₂ atmosphere which had an oxygen partial pressure of 1×10⁻⁹ kPa and which was at the atmospheric pressure, whereby the molded body was sintered, and then cooled to the room temperature (Step 3).

Thereafter, the sintered body was kept at 1000° C. for 3 hours using two different atmospheres, a N₂ atmosphere which had an oxygen partial pressure of 2×10⁻³ kPa (oxygen concentration: about 20 ppm) and which was at the atmospheric pressure and a normal air atmosphere (oxygen partial pressure was about 2.1×10 kPa), whereby the recovery heat treatment was carried out (Step 4).

Electrodes were formed on the resultant sintered body, and a voltage of 4000 V/mm was applied across the sintered body in a silicone oil at 150° C., whereby the polarization treatment was carried out. As a result, a piezoelectric ceramic was obtained.

(2) Measurement of Characteristics

The piezoelectric constant d33 and Curie temperature of the manufactured ceramics were measured through the same procedure as that employed for Examples 1 to 8.

(3) Results and Consideration

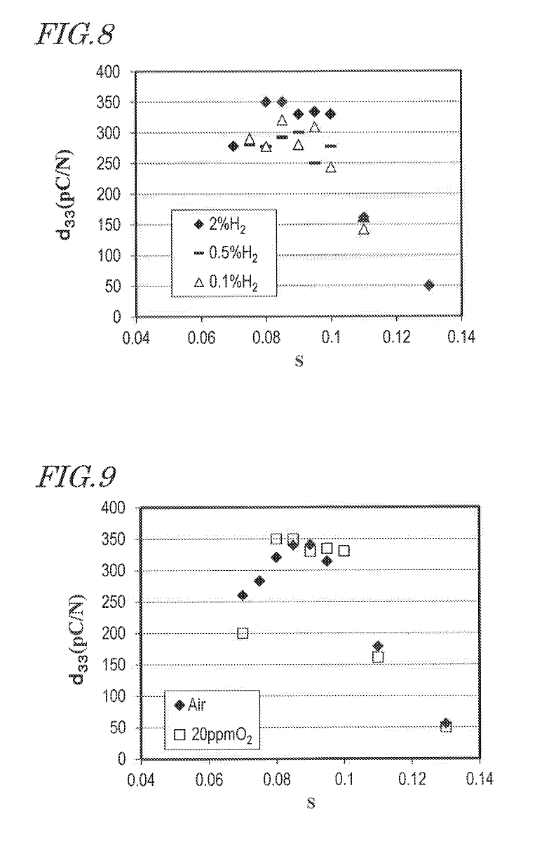

FIG. 9 is a graph where the horizontal axis represents s of Formula (1) (the quantitative ratio of BaZrO₃), and the vertical axis represents the piezoelectric constant d33. Table 13 shows numerical values of the graph.

It can be seen that, so long as s is constant, ceramics which have generally equal piezoelectric constants d33 can be obtained even when the oxygen partial pressure is varied within a wide range from 2×10⁻³ kPa to the normal air atmosphere (the oxygen partial pressure was about 2.1×10 kPa).

TABLE 13

d33(pC/N)

| | 2 × 10⁻³ | 2 × 10¹ |
|---|---|---|
| s | (kPa) | (kPa) |
| 0.13 | 56 | 50 |
| 0.11 | 179 | 161 |
| 0.1 | — | 330 |
| 0.095 | 314 | 334 |
| 0.09 | 341 | 330 |
| 0.085 | 340 | 350 |
| 0.08 | 320 | 350 |
| 0.075 | 283 | — |
| 0.07 | 260 | 200 |

(—: Not measured)

### 10. Example 21

It was examined how the successfulness of polarization changes depending on the sintering temperature using the composition of Example 3.

(1) Manufacture of Piezoelectric Ceramic

The raw materials were prepared at Step 1 and molded at Step 2 in the same way as Example 3 as shown in FIG. 1.

Thereafter, the resultant molded body was subjected to reductive sintering according to the temperature profile and atmosphere illustrated in FIG. 2 with varying sintering temperatures, 1050° C., 1100° C., 1200° C., 1250° C. and 1300° C., while the other conditions were the same as those of Example 3.

Thereafter, the recovery heat treatment was carried out at Step 4 as shown in FIG. 1.

Electrodes were formed on the resultant sintered body, and a voltage of 4000 V/mm was applied across the sintered body in a silicone oil at 150° C., whereby the polarization treatment was carried out.

### (2) Results and Consideration

As seen from Table 14, ceramics sintered at 1100° C. to 1300° C. are capable of being polarized. In the piezoelectric ceramics sintered at 1050° C. and 1350° C., conduction occurred during polarization, and a ceramic having piezoelectric characteristics was not obtained.

TABLE 14

| | Sintering | |
|---|---|---|
| | Temperature | Successfulness |
| Composition | (° C.) | of Polarization |
| 0.90(K_{0.45}Na_{0.5}Li_{0.05})NbO₃—0.09BaZrO₃—0.01(La_{0.5}Na_{0.5})TiO₃ | 1050 | Failure |
| | 1100 | Success |
| | 1200 | Success |
| | 1300 | Success |
| | 1350 | Failure |

### 11. Example 22

It was examined how the successfulness of polarization changes depending on the temperature of the recovery heat treatment using the composition of Example 3.

(1) Manufacture of Piezoelectric Ceramic

The raw materials were prepared at Step 1, molded at Step 2, and sintered at Step 3 in the same way as Example 3 as shown in FIG. 1.

Thereafter, the recovery heat treatment was carried out according to the temperature profile and atmosphere illustrated in FIG. 2 with varying recovery heat treatment temperatures, 450° C., 500° C., 600° C., 800° C., 1000° C. and 1200° C., while the other conditions were the same as those of Example 3.

Electrodes were formed on the resultant sintered body, and a voltage of 4000 V/mm was applied across the sintered body in a silicone oil at 150° C., whereby the polarization treatment was carried out.

(2) Results and Consideration

As seen from Table 15, ceramics which were subjected to the recovery heat treatment at 500° C. to 1200° C. were capable of being polarized. In a piezoelectric ceramic which was subjected to the recovery heat treatment at 450° C., conduction occurred during polarization, and a ceramic having piezoelectric characteristics was not obtained. When the heat treatment was carried out at 1300° C., the ceramic melted and deformed, so that the polarization process itself could not be carried out.

TABLE 15

| | Recovery | |
|---|---|---|
| | Heat Treatment | Successfulness |
| Composition | Temperature (° C.) | of Polarization |
| 0.90(K_{0.45}Na_{0.5}Li_{0.05})NbO₃—0.09BaZrO₃—0.01(La_{0.5}Na_{0.5})TiO₃ | 450 | Failure |
| | 500 | Success |
| | 600 | Success |
| | 800 | Success |
| | 1000 | Success |
| | 1200 | Success |
| | 1300 | Failure |

### INDUSTRIAL APPLICABILITY

A piezoelectric ceramic, piezoelectric element, and method for manufacturing piezoelectric ceramic of the present invention are suitably applicable to piezoelectric elements for use in the fields of electronics, mechatronics, automobiles, etc.

1. A method for manufacturing piezoelectric ceramic, comprising the steps of:
preparing a raw material so as to contain A, B, Ba and Zr as major constituents in a composition ratio represented by the following formula:
(1-s)ABO₃-sBaZrO₃
(where A is at least one element selected from alkali metals, B is at least one of transition metal elements and includes Nb, 0.06<s≦0.15);
molding the raw material to obtain a molded body;
sintering the molded body in a reducing atmosphere; and
subjecting a sintered body obtained at the sintering step to a heat treatment in an oxidative atmosphere.

2. A method for manufacturing piezoelectric ceramic, comprising the steps of:
preparing a raw material so as to contain A, B, Ba, Zr, R, M and Ti as major constituents in a composition ratio represented by the following formula:
(1-s−t)ABO₃-sBaZrO₃-t(R.M)TiO₃
(where A is at least one element selected from alkali metals, B is at least one of transition metal elements and includes Nb, R is at least one of rare earth elements (including Y), M is at least one element selected from alkali metals, 0.05<s≦0.15, 0<t≦0.03, s+t>0.06);
molding the raw material to obtain a molded body;
sintering the molded body in a reducing atmosphere; and
subjecting a sintered body obtained at the sintering step to a heat treatment in an oxidative atmosphere.

3. The method of claim 1, wherein the A includes at least Li, K and Na.

4. The method of claim 2, wherein the M includes at least Na.

5. The method of claim 1, wherein in the sintering step, an oxygen partial pressure of the reducing atmosphere is not more than 10⁻⁴ kPa.

6. The method of claim 1, wherein in the sintering step, the oxygen partial pressure of the reducing atmosphere is not less than 10⁻¹² kPa and not more than 10⁻⁴ kPa.

7. The method of claim 1, wherein in the sintering step, the reducing atmosphere contains hydrogen in a range of not less than 0.01% and not more than 5%.

8. The method of claim 1, wherein in the sintering step, a sintering temperature is not less than 1100° C. and not more than 1300° C.

9. The method of claim 1, wherein in the sintering step, a sintering duration is not less than 0.1 hour and not more than 30 hours.

10. The method of claim 1, wherein in the heat treatment step, an oxygen partial pressure of the oxidative atmosphere exceeds 10⁻⁴ kPa.

11. The method of claim 1, wherein in the heat treatment step, a heat treatment temperature is not less than 500° C. and not more than 1200° C.

12. A piezoelectric ceramic manufactured by the manufacturing method as set forth in claim 1.

13. The piezoelectric ceramic of claim 12, wherein
the s is in a range of 0.065≦s≦0.10, and
a piezoelectric constant d33 of the piezoelectric ceramic is not less than 250 pC/N.

14. A piezoelectric ceramic manufactured by the manufacturing method as set forth in claim 2.

15. The piezoelectric ceramic of claim 14, wherein
the s is in a range of 0.065≦s≦0.10,
the t is in a range of 0.005<t≦0.015, and
a piezoelectric constant d33 of the piezoelectric ceramic is not less than 270 pC/N.

16. A piezoelectric element, comprising:
the piezoelectric ceramic as set forth in claim 12; and
a plurality of electrodes which are in contact with the piezoelectric ceramic.

17. The piezoelectric element of claim 16, wherein the plurality of electrodes contain a base metal.
